(19) United States
(12) Patent Application Publication
(10) Pub. No.: US 2013/0149838 A1
(43) Pub. Date: Jun. 13, 2013

(54) PROCESS FOR FILLING DEEP TRENCHES IN A SEMICONDUCTOR MATERIAL BODY, AND SEMICONDUCTOR DEVICE RESULTING FROM THE SAME PROCESS

(71) Applicant: STMICROELECTRONICS S.R.L., Agrate Brianza (IT)

(72) Inventors: Mario Giuseppe Saggio, Aci Castello (IT); Domenico Murabito, Catania (IT); Letterio Fiore, Messina (IT); Giuseppe Morale, Catania (IT)

(73) Assignee: STMICROELECTRONICS S.R.L., Agrate Brianza (IT)

(21) Appl. No.: 13/749,526

(22) Filed: Jan. 24, 2013

Related U.S. Application Data
(63) Continuation-in-part of application No. PCT/IB2011/001724, filed on Jul. 26, 2011.

(30) Foreign Application Priority Data
Jul. 26, 2010 (IT) TO2010A000642

(51) Int. Cl. H01L 21/762

(52) U.S. Cl. CPC H01L 21/762
USPC 438/429

(57) ABSTRACT

A process for manufacturing a semiconductor device envisages the steps of: providing a semiconductor material body having at least one deep trench that extends through said body of semiconductor material starting from a top surface thereof; and filling the deep trench via an epitaxial growth of semiconductor material, thereby forming a columnar structure within the body of semiconductor material. The manufacturing process further envisages the step of modulating the epitaxial growth by means of a concurrent chemical etching of the semiconductor material that is undergoing epitaxial growth so as to obtain a compact filling free from voids of the deep trench; in particular, a flow of etching gas is introduced into the same reaction environment as that of the epitaxial growth, wherein a flow of source gas is supplied for the same epitaxial growth.

### BACKGROUND

1. Technical Field

The present disclosure relates to a process for filling deep trenches in a body made of semiconductor material, and to a semiconductor device resulting from the same process. In particular, the present disclosure will make explicit reference, without this implying any loss in generality, to a semiconductor power device (for example a diode, a MOSFET, an IGBT, or a bipolar transistor) of the charge-balance type.

2. Description of the Related Art

As is known, a wide range of solutions have been developed in recent years to increase the efficiency of semiconductor power devices, in particular in terms of increase in the corresponding breakdown voltage and reduction in the corresponding output resistance.

For instance, U.S. Pat. No. 6,586,798, U.S. Pat. No. 6,228,719, U.S. Pat. No. 6,300,171 and U.S. Pat. No. 6,404,010 disclose vertical-conduction semiconductor power devices, in which, within an epitaxial layer, which forms part of a drain region having a given type of conductivity (for example a conductivity of an N type), columnar structures of opposite conductivity (in the example a conductivity of a P type) are provided. The columnar structures have a concentration of dopant such as to balance the amount of charge of the epitaxial layer in such a way as to create a substantial charge balance (so-called multi-drain (MD) technology or superjunction (SJ) technology).

This charge balance enables high breakdown voltages to be obtained, as illustrated in the graph of FIG. 1, which highlights that the value of the breakdown voltage (BV) of a semiconductor device has a maximum at a point corresponding to a perfect charge balance in the corresponding drain layer (Nd representing the concentration of dopant species of an N type, and Na the concentration of dopant species of a P type). In addition, the high concentration of the epitaxial layer enables a low output resistance (and hence low conduction losses) to be obtained.

Manufacturing of the columnar structures may envisage a sequence of steps of growth of epitaxial layers, for example of an N type, each step being followed by a step of implantation of dopant of an opposite type, in this case of a P type. The implanted regions are stacked so as to form the columnar structures. Next, in order for the columnar structure constituted by the alternation of implantations and epitaxial growths to be continuous, it is required to increase the thermal budget of the device. Finally, body regions of the power device are provided in contact with the columnar structures, in such a way that the columnar structures constitute an extension of the body regions within the drain region.

The evolution of this technology has led to a progressive increase in the density of the elementary strips that make up the devices in order to increase further the concentration of charge of the epitaxial layer and obtain devices that, given the same breakdown voltage (linked substantially to the height of the columnar structures), have a lower output resistance. On the other hand, however, the increase in the density of the elementary strips has led to a corresponding increase in the number of the steps of epitaxial growth (up to a number even greater than ten) and of the thermal budget of the resulting devices, and consequently an increase in the manufacturing costs and the time involved, as well as in the defectiveness (which is intrinsically linked to the steps of epitaxial growth).

Alternative techniques for manufacturing charge-balance columnar structures have consequently been developed, which envisage in particular formation of deep trenches within a surface portion of a wafer of semiconductor material, for example through a corresponding epitaxial layer, and subsequent filling of the same trenches with semiconductor material appropriately doped to obtain a charge balance.

For instance, solutions have been proposed in which the trenches are filled via steps of non-selective epitaxial growth of semiconductor material, alternated with distinct and separate steps of etching of surface growth portions (so-called “multi-step process”).

As a whole, the solutions described for manufacturing of power devices with charge-balance structures have not proven altogether satisfactory, both as regards the complexity and costs of production and as regards obtaining a real charge balance (for instance, on account of a poor uniformity of spatial distribution of charge or on account of the presence of residual defects, in particular voids in filling of the trenches).

In particular, the steps of epitaxial filling of the deep trenches have proven critical, especially in the case where the same trenches have high values of aspect ratio or shape factor, i.e. high ratios between depth and width.

In fact, as highlighted in FIG. 2, the rate of epitaxial growth (V_{growth}) decreases the greater the depth in the trench and the further the distance from the surface of the wafer of semiconductor material, as a consequence of the reduction in the concentration of reaction gases with depth. Consequently, the fronts of growth on the side walls of the trench at the surface may meet before filling of the trench itself has been completed; once the filling process is completed, voids may thus remain within the trenches that have been filled. These voids have dimensions that in some cases may even be large and comparable with the width of the same trenches.

The presence of these voids, and in general of residual defects in the filled trenches, may jeopardize the electrical characteristics of the resulting semiconductor devices, for instance the electrical characteristics in the reverse-biasing region.

Yamauchi S et al: “200V Fabrication of high aspect ratio doping region by using trench filling of epitaxial SI growth”, PROCEEDINGS OF THE 13TH INTERNATIONAL SYMPOSIUM ON POWER SEMICONDUCTOR DEVICES, 4 Jun. 2001, Osaka, pages 363-366, discloses a multi-step process for filling a high aspect ratio trench with a reduced void size, alternating low-temperature epitaxial growth steps with high-temperature etching steps.

Yamauchi S et al: “200V super junction MOSFET fabricated by high aspect ratio trench filling”, PROCEEDINGS OF THE 18TH INTERNATIONAL SYMPOSIUM ON POWER SEMICONDUCTOR DEVICES & ICS, IEEE PISCATAWAY, NJ, USA, 2006, page 4, discloses filling of a high aspect ratio trench using an anisotropic epitaxial growth, where a chlorine source gas is used to prevent the silicon epitaxial growth at the top of the trench, while a silicon epitaxial layer is grown from the bottom of the trench.

### BRIEF SUMMARY

One embodiment of the present disclosure solves, either totally or partially, the problems highlighted previously, and in particular provides a manufacturing process that will enable devices with improved electrical characteristics to be obtained and that will have a good degree of simplicity of production and contained manufacturing costs. Consequently, according to some embodiments the present disclosure, a process for manufacturing a semiconductor device, and a corresponding semiconductor device are provided substantially as defined in the annexed claims.

### BRIEF DESCRIPTION OF THE SEVERAL VIEWS OF THE DRAWINGS

For a better understanding of the present disclosure, preferred embodiments thereof are now described, purely by way of non-limiting example and with reference to the attached drawings, wherein:

FIGS. 1 and 2 show graphs of electrical and physical quantities regarding semiconductor devices and manufacturing processes of a conventional type;

FIGS. 3a-3g show schematic cross sections of a body made of semiconductor material, during a process for filling deep trenches, according to one embodiment of the present disclosure;

FIG. 4 shows plots of rates of growth and etching adopted during substeps of the filling process illustrated in FIGS. 3a-3g;

FIG. 5 shows plots of ratios of flows of gases employed during substeps of the filling process illustrated in FIGS. 3a-3g;

FIGS. 6a-6g show schematic cross sections of a body made of semiconductor material, during a process for filling deep trenches, according to a different embodiment of the present disclosure;

FIGS. 7 and 8 show schematic cross sections of a semiconductor device provided at the end of the process of filling of the deep trenches;

FIGS. 9a and 9b show, respectively, a cross section and a top plan view, of an edge-termination structure of the semiconductor device of FIG. 8, in a first variant embodiment; and

FIGS. 10a and 10b show, respectively, a cross section and a top plan view, of an edge-termination structure of the semiconductor device of FIG. 8, in a second variant embodiment.

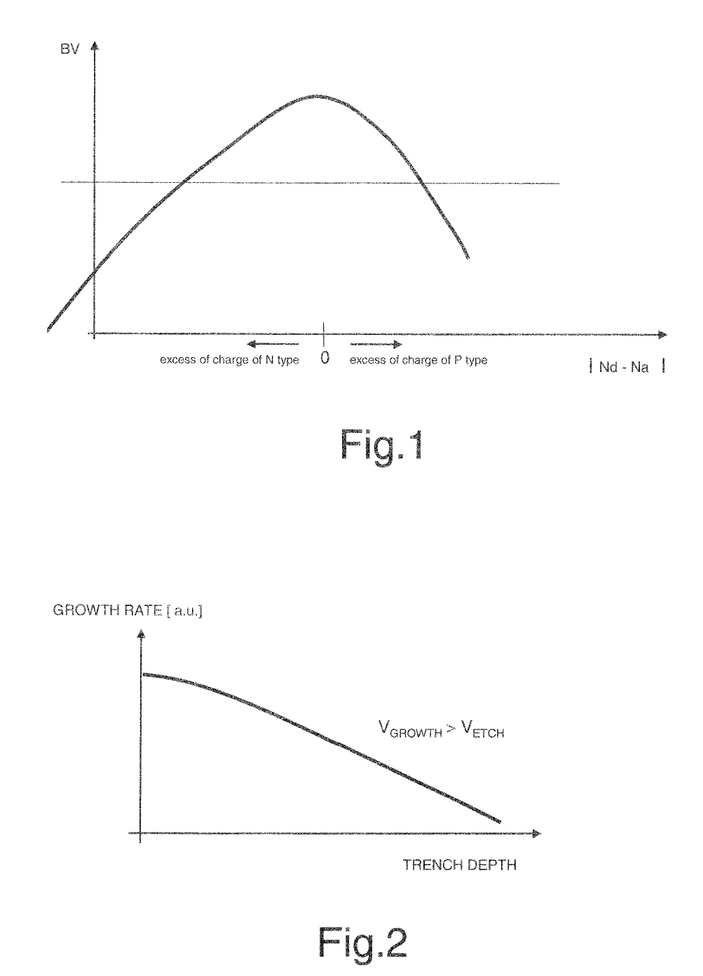

### DETAILED DESCRIPTION

A manufacturing process according to one embodiment of the present disclosure is now described, with particular reference to the manufacturing of a charge-balance semiconductor device, in which columnar structures having a given conductivity are formed within a body made of semiconductor material of opposite conductivity, for balancing the overall charge thereof. It is to be noted, however, that the process that will be described finds general application for providing uniform filling, free from defects (namely, voids), of trenches previously made within a body of semiconductor material.

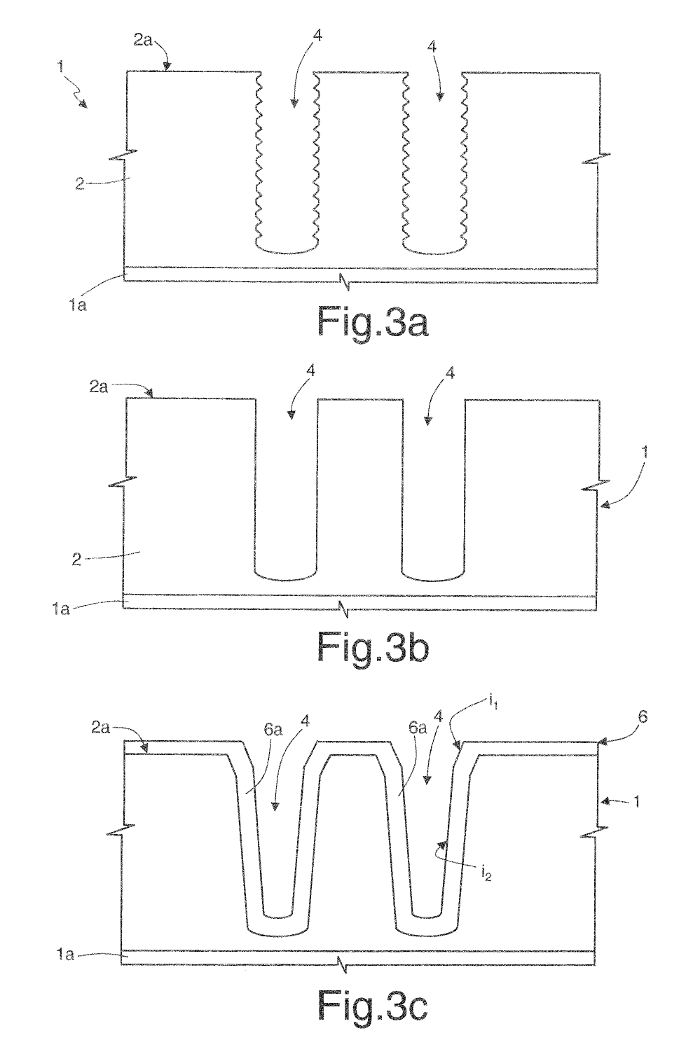

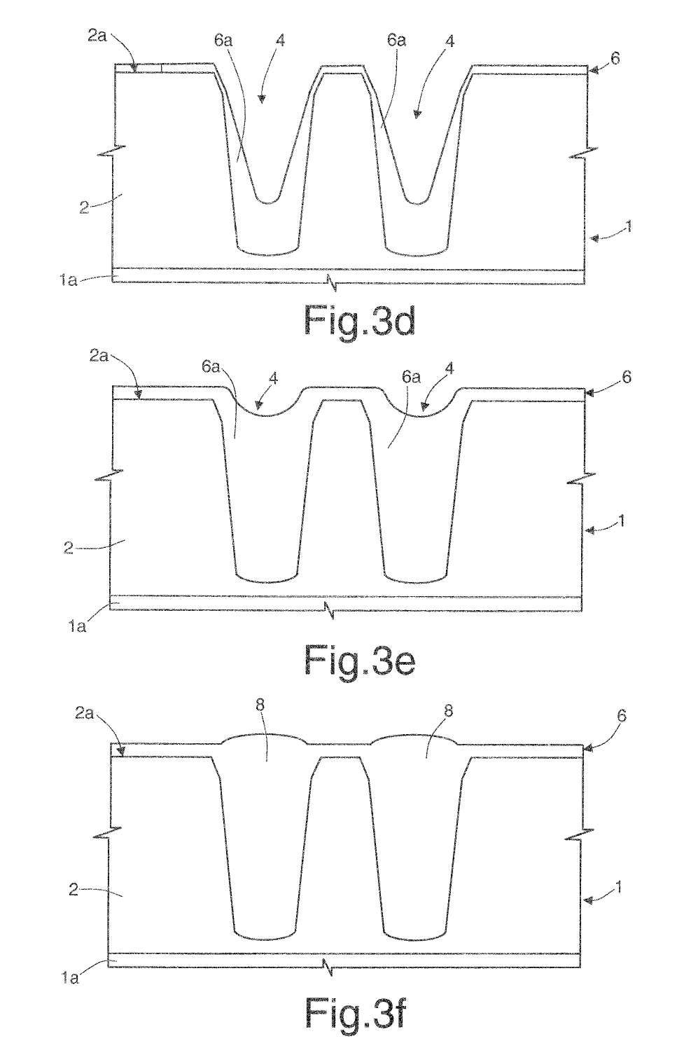

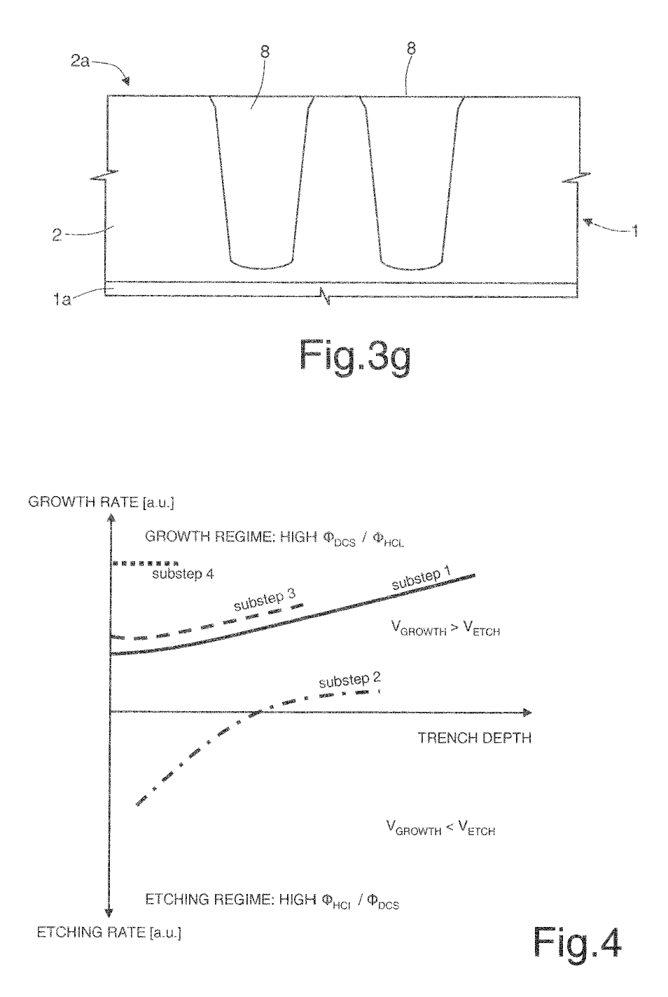

FIG. 3a (not drawn to scale, as neither are the subsequent figures) shows a wafer 1 of semiconductor material, in particular silicon, including a substrate 1a and a structural layer 2, set on the substrate 1a and having a first type of conductivity, for example of an N type, and a top surface 2a; for instance, the structural layer 2 is an epitaxial layer previously grown on the substrate 1a.

Deep trenches 4 extend vertically (i.e., in the direction transverse to the cross section of FIG. 3a) through a surface portion of the structural layer 2, in the direction of the depth of said structural layer 2 (towards the underlying substrate 1a). The deep trenches 4 are, for example, obtained with photolithographic techniques of masking and anisotropic dry chemical etching (not described in detail herein).

FIG. 3a, as also the subsequent figures, shows for greater clarity an enlargement of a surface portion of the wafer 1, which encloses a single pair of mutually adjacent deep trenches 4 (in a position corresponding to which two corresponding strips of a semiconductor device will be formed, as clarified hereinafter). It is, however, clear that the process steps described hereinafter also regard the remaining part of the wafer 1.

Deep trenches 4 have substantially vertical side walls (orthogonal to the top surface 2a), with an angle of inclination, with respect to the same top surface 2a, comprised, for example between 88° and 90°, and a high aspect ratio. For instance, in one embodiment the deep trenches 4 have a depth of 30 μm and a width of between 1.5 μm and 3 μm; and in another embodiment a depth of 10 μm and a width of between 0.5 μm and 1.5 μm (the corresponding depth thus being, for instance, ten to twenty times the corresponding width).

As is known, the depth of the deep trenches 4 determines the voltage class of the resulting semiconductor device. For instance, to a depth of 5 μm there corresponds a voltage class of 100 V, whereas to a depth of 30 μm there corresponds a voltage class of 600V. The cutoff voltage of the resulting semiconductor device may moreover vary as a function of the thickness of the structural layer 2; for instance, the cutoff voltage of the resulting device may vary between 100 V and 1500 V, according to the thickness of the structural layer 2.

In addition, the distance of lateral separation (measured parallel to the top surface 2a and transverse to the direction of the depth) between two adjacent deep trenches 4 is, for example, between 3 μm and 6 μm; this separation distance, together with the width of the same deep trenches 4, defines the periodicity of the structure of the final semiconductor device (which is, in fact, made up of a plurality of elementary structures).

As illustrated in FIG. 3b, the process proceeds with a step of surface treatment of the internal side walls of the deep trenches 4, in particular including a thermal treatment of annealing in hydrogen environment at a high temperature (for instance, from 1000° C. to 1150° C.). This treatment enables removal of damages due to the previous dry etching (which has led to formation of the deep trenches 4) and moreover possible removal of surface roughness on the side walls (so-called “scallops”). In the same process step, there is moreover obtained removal of possible oxide formed in the previous process steps on the side walls, which at the end of this step are hence smooth and uniform.

In particular, the aforesaid annealing may be carried out in the same reactor as the one in which the epitaxial growth for filling the deep trenches 4 will then be carried out.

The process proceeds then with filling of the deep trenches 4, in particular through a uniform epitaxial filling free from voids of the same deep trenches with monocrystalline silicon doped with a second type of conductivity, in the example described, of a P type (for instance doped with boron ions).

In particular, in order to obtain a uniform filling of the deep trenches 4, one aspect of the present disclosure envisages use, within the reaction environment for the epitaxial growth of an appropriate chemical-etching agent mixed to the source gas used for the epitaxial growth, the chemical-etching agent being able to modulate appropriately the rate of epitaxial growth. There is thus obtained an appropriate dynamic balance between the epitaxial growth along the walls of the deep trenches 4 and the simultaneous removal of part of the layer grown, and possibly of pre-existing material, by means of chemical etching, in order to obtain homogeneously filled columnar structures. In other words, the disclosure proposes an in situ balance (i.e., a balance obtained within the same environment of epitaxial growth) of the growth and of the simultaneous etching of an epitaxial layer, such as to modulate appropriately and dynamically the shape of the regions of material grown and of the deep trenches 4 in the filling step, and thus obtain a uniform filling of the same deep trenches 4.

For instance, one aspect of the present disclosure envisages the use, as a chemical-etching agent, of hydrochloric acid (HCl), appropriately supplied in the reaction environment together with the silicon source gas, for example, constituted by dichlorosilane (DCS—SiH₂Cl₂). As already highlighted, the role of hydrochloric acid (HCl) is to modulate appropriately the rate of epitaxial growth, for instance in such a way that the epitaxial growth increases in the deep trenches 4 the further the distance from the surface (hence reversing the profile provided by the epitaxial growth alone—see FIG. 2).

In the reaction environment there is also present a carrier gas, which enables modulation of the partial pressure of the reagent species and participates also in the overall reaction of epitaxial growth; by way of example, molecular hydrogen (H₂) may be used as such a carrier gas.

As described in detail hereinafter, within the same reaction chamber for the epitaxial growth an appropriate doping agent is moreover supplied, such as to enable a desired dopant profile to be obtained within the columnar structure that is formed within each deep trench 4. For instance, for this purpose an appropriate flow of diborane (B₂H₆) is used, which is able to form a dopant of a P type within the columnar structures being formed inside the deep trenches 4.

According to a peculiar aspect of the present disclosure, the step of epitaxial growth for filling the deep trenches 4 is articulated in a sequence of substeps, in each of which the process conditions, and in particular the flows of the various gases that participate in combination in the resulting growth, are varied. Within the various substeps, during the epitaxial process, the competitive behaviour of the etching agent (in the example, HCl) and of the growth agent (in the example, DCS) is appropriately exploited so as to modulate the shape of the deep trenches 4 and of the material grown within the same deep trenches 4, and prevent formation of defects (in particular, residual voids).

An embodiment envisages in particular that the step of filling by epitaxial growth comprises a sequence of four substeps, highlighted in the plot of FIG. 4 in terms of the corresponding rates of growth and etching, each of which is distinct and characterized by an appropriate competitive action between etching and epitaxial growth, given by a corresponding ratio between the flow of HCl and the flow of DCS supplied in the reaction environment (ratio φN_{HCl}/Φ_{DCS}).

In detail, during a first substep an average value of the ratio Φ_{HCl}/Φ_{DCS} is used (for example, comprised between 4 and 9), such as to obtain a rate of growth at the bottom of the deep trench 4 higher than the rate of growth at the top surface 2a of the structural layer 2 (it is to be noted again that the appropriate balance of the reaction species hence enables inversion of the usual profile of epitaxial growth, with a rate of growth at the surface higher than the rate of growth at the bottom). In addition, in this first substep, a higher rate of etching is determined at the top surface 2a, in particular in a lateral direction. In general, during the first substep the process evolves in any case in a growth regime, i.e., with a predominance of the growth of epitaxial material as compared to etching of the grown (and possibly pre-existing) material.

As illustrated in FIG. 3c, after the first substep of the filling process, a filling layer 6 of epitaxial silicon, in particular monocrystalline silicon, is formed within the deep trenches 4 and, in a non-selective manner, also on the top surface 2a. The filling layer 6 includes filling regions 6a within each deep trench 4, which coat the internal lateral walls and the bottom thereof.

In particular, thanks to the action of competitive etching exerted by the flow of HCl, the deep trenches 4, and the corresponding filling regions 6a, have a profile that is tapered, flared or funnel-shaped, at the respective opening, narrowing from the surface towards the bottom. Equivalently, the deep trenches 4, and the corresponding filling regions 6a, have side walls with a first inclination, designated by i₁, at the surface, and a second inclination, smaller than the first inclination (with respect to the vertical direction, or the direction of the depth), designated by i₂, for the remaining part of the same trenches. Etching has in fact a greater effect at the surface than at the bottom of the deep trenches 4, possibly causing also a removal in a lateral direction of a portion of surface material of the structural layer 2 (set between two adjacent deep trenches 4), i.e., of a material existing prior to the epitaxial growth.

In a subsequent second process substep (it is to be noted that the transition from one substep to the next is determined on the basis of the evolution of the shape of the partially filled trench and of the thickness of grown epitaxial silicon, see again FIG. 4, a higher value of the Φ_{HCl}/Φ_{DCS} ratio is used (for example comprised between 9 and 12) such as to obtain a high effect of etching (and of removal of material) at the top surface 2a of the structural layer 2, and, again, an epitaxial growth at the bottom of the deep trenches 4. In particular, the competitive process evolves into etching regime (i.e., etching is predominant as compared to growth) in a surface region of the deep trenches 4, whilst it evolves into a growth regime (i.e., growth is as a whole predominant as compared to etching) in a deep region of the deep trenches 4.

As illustrated in FIG. 3d, this process substep entails a remodelling of the deep trenches 4 and of the filling regions 6a within the same deep trenches 4, which assume a “V” profile, i.e., with side walls that have an increased angle of inclination from the surface to the bottom, again considered with respect to the vertical direction (the angle of inclination is, for instance, between 80° and 87°). There occurs in particular an increase in the thickness of the filling regions 6a in an area corresponding to the bottom of the deep trenches 4, and an increase in the width of the mouth of the deep trenches 4 (due to etching in a lateral direction of the epitaxial layer grown, and possibly of the pre-existing surface material of the structural layer 2). Once again, the deep trenches 4 and the corresponding filling regions 6a have a characteristic profile, tapered at the top surface 2a.

In a third process substep, subsequent to the aforesaid second substep (see again FIG. 4), conditions of etching/growth substantially equivalent to those used during the first substep are applied, i.e., a ratio Φ_{HCl}/Φ_{DCS} of average value and not much less than the one used in the aforesaid first substep (for example, comprised between 3 and 8). This ratio determines again a regime of growth throughout the depth of the deep trenches 4 (a depth that in the mean time has clearly decreased, on account of the growth of epitaxial material on the bottom), and a rate of growth at the bottom higher than the rate of growth at the surface.

As illustrated in FIG. 3e, the third substep of the filling process causes a substantially complete filling of the deep trenches 4, with the corresponding filling regions 6a that occupy in a way that is uniform and altogether free from voids the inside of the deep trenches 4. At the end of the third substep, the deep trenches 4 may still present a depression at the top surface 2a (i.e., a region not yet filled, of small depth). It is to be noted in particular that this substantially complete and uniform filling is the effect of the appropriate remodelling of the shape of the deep trenches 4 and of the regions of epitaxial growth within the deep trenches 4, during the previous process substeps, as highlighted previously, such as not to cause a premature closing of the fronts of growth from the side walls, before filling has occurred at the bottom.

The process terminates with a fourth substep, of overgrowth, carried out in complete growth regime, i.e., with a ratio Φ_{HCl}/Φ_{DCS} of a low value, less than the corresponding values assumed in the previous substeps (for instance, comprised between 2 and 4). In particular, a substantially uniform rate of growth is determined throughout the depth of the deep trenches 4 not yet occupied by the corresponding filling regions 6a.

As illustrated in FIG. 3f, this substep determines effectively complete filling of the deep trenches 4 and formation of columnar structures 8 within the structural layer 2, constituted by epitaxial material that is uniform, compact, and free from voids. It is to be noted that the columnar structures 8 have a swelling in a region corresponding to the top surface 2a of the structural layer 2.

The filling process terminates with a possible step of surface planarization (CMP—Chemical Mechanical Planarization), as illustrated in FIG. 3g, in order to remove the filling layer 6 on the top surface 2a and the aforesaid swellings of the columnar structures 8 and planarize the top surface 2a of the structural layer 2.

At the end of the filling process, the columnar structures 8 have moreover an appropriate level and profile of doping, obtained, as previously mentioned, by supplying a flow of an appropriate dopant species within the same reaction environment as the one in which the epitaxial growth is carried out (the doping of the columnar structures 8 is hence obtained simultaneously with the epitaxial filling of the deep trenches 4, modulated by the concomitant etching of material).

For instance, in a possible embodiment, the columnar structures 8 have a level of doping such as to balance the charge present in the structural layer 2, thus providing charge-balance structures, and moreover have a doping profile that is uniform vertically throughout their depth.

In detail, the doping factor may be expressed as the ratio between the flow of the dopant species (in this case, diborane, Φ_{B2H6}), and the total flow of the remaining species supplied in the reaction environment:

$$\frac{{Φ}_{B 2 H 6}}{{Φ}_{DCS} + {Φ}_{H 2} + {Φ}_{HCl}} \approx \frac{{Φ}_{B 2 H 6}}{{Φ}_{H 2}} ;$$

$${Φ}_{H 2} ≫ {Φ}_{DCS} , {Φ}_{HCl}$$

The doping factor is hence proportional to the flow of diborane, once the value of the flow of carrier gas necessary for the reaction of epitaxial growth has been established (it is to be noted that the flow of the carrier gas, Φ_{H2}, is considerably greater than the individual flows Φ_{DCS} and Φ_{HCl}; for instance, flows Φ_{DCS} and Φ_{HCl} of approximately 1 l correspond to a flow Φ_{H2} of approximately 30 l).

In addition, given the competitive reaction between B₂H₆ and HCl, which tends to render the concentration of dopant in the reaction environment deplete, one aspect of the present disclosure envisages regulation of the flow of B₂H₆ as a function also of the flow of HCl.

In particular, in order to maintain a distribution of dopant uniform within the columnar structures 8, the flows are regulated in such a way that the ratio Φ_{B2H6}/Φ_{HCl} (i.e., the ratio between the flow of the dopant species and the flow of the etching agent) remains constant during the entire filling process (and during the corresponding four process substeps), notwithstanding the variation in the ratio Φ_{HCl}/Φ_{DCS}, for the reasons described previously of modulation of epitaxial growth. Basically, the flow of B₂H₆ is varied and regulated as a function of the flow of HCl, in a way corresponding thereto.

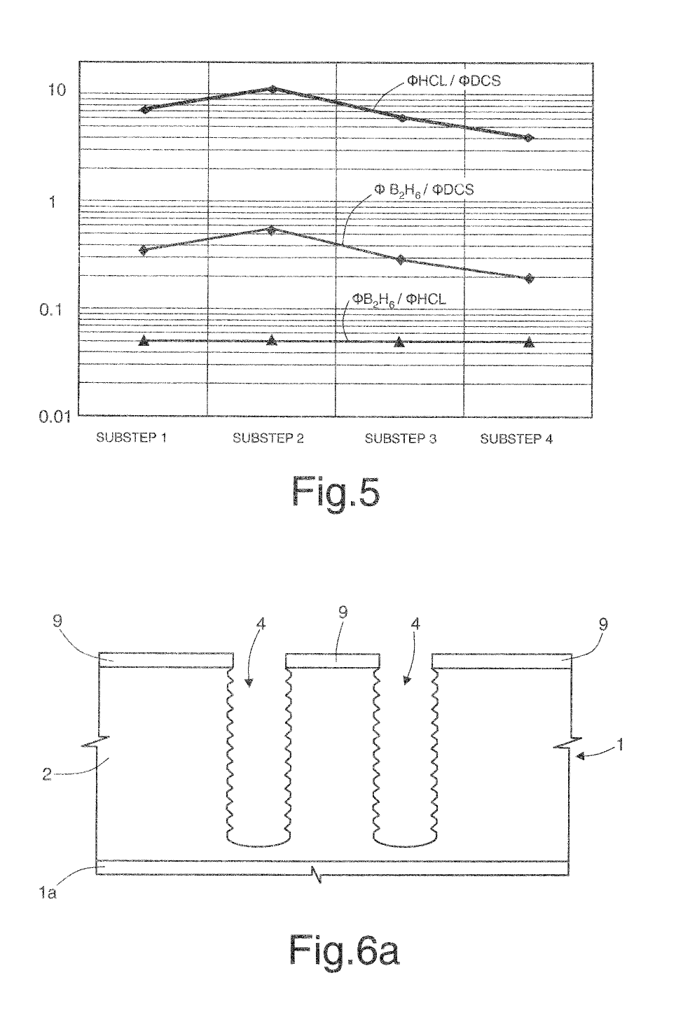

FIG. 5 illustrates the profile of the values of the aforesaid ratios of flows, during the four substeps of the process of filling the deep trenches 4; in particular, it is highlighted that the ratio Φ_{B2H6}/Φ_{HCl} remains effectively constant in order to obtain a uniform doping profile of the columnar structures 8, and the ratios Φ_{B2H6}/Φ_{DCS} and Φ_{HCl}/Φ_{DCS} have substantially corresponding trends.

Evidently, it is, however, possible to obtain different doping profiles, according to the specific manufacturing specifications, by appropriately varying the flow of the dopant species within the reaction environment during the process of filling of the deep trenches 4.

A different embodiment of the filling process envisages a selective growth of the epitaxial material, limited to the deep trenches 4 alone (the epitaxial growth does not, instead, involve the top surface 2a of the structural layer 2).

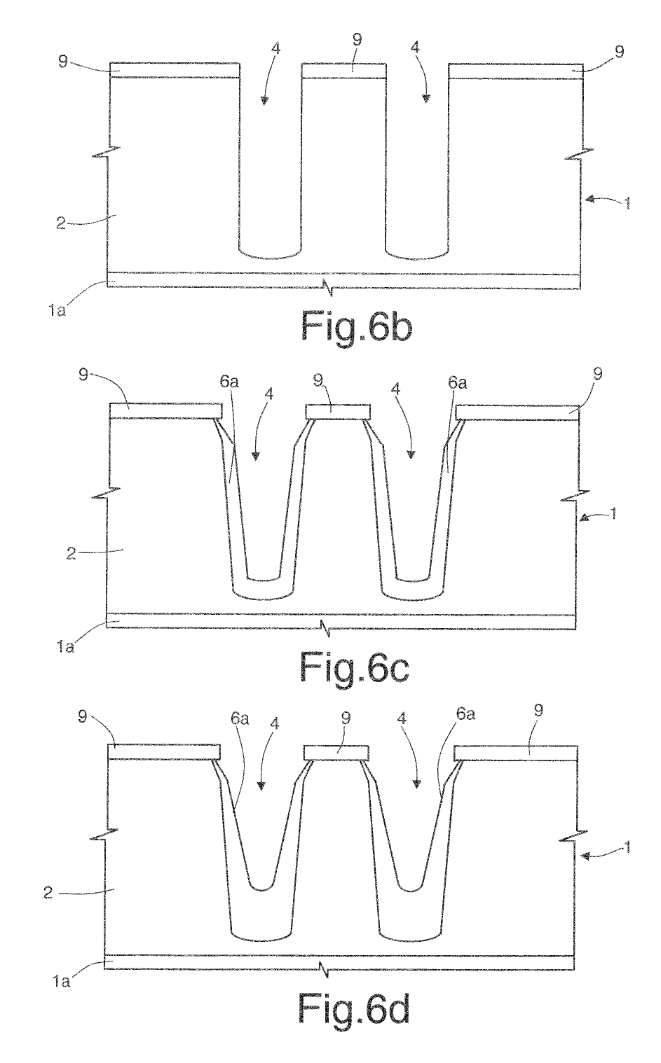

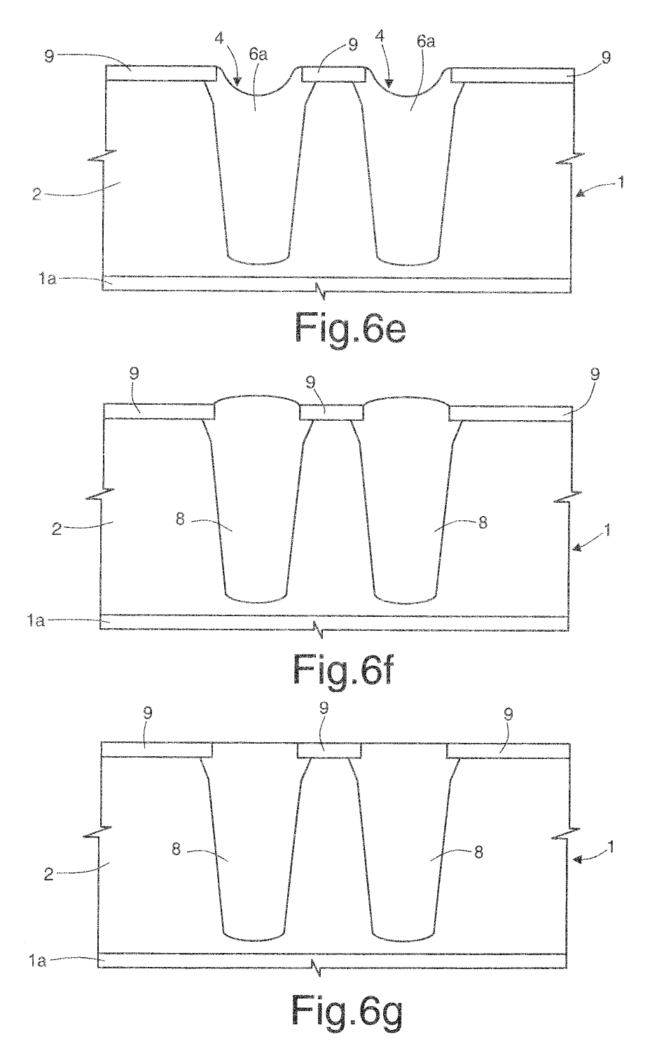

For this purpose, as illustrated in FIGS. 6a-6g, which represent the sequence of the substeps of the filling process (not described again in detail), in an initial step of the process, a mask (so-called “hard mask”) layer 9 is formed on the top surface 2a of the structural layer 2 (FIG. 6a); the mask layer 9 is made, for example, of silicon oxide or silicon nitride, acting as “stopping layer”, i.e., having the function of stopping the steps of etching and growth outside the deep trenches 4. The mask layer 9 in fact coats the top surface 2a, leaving only the deep trenches 4, and in particular the corresponding mouths at the top surface 2a, exposed. Evidently, the mask layer 9 may be present prior to the deep trenches 4 and be used as etching mask for forming the same deep trenches 4. Advantageously (see FIG. 6g), the mask layer 9 acts as stopping layer for the CMP process, preventing in particular any undesirable over-etching of the underlying structural layer 2.

In addition, as illustrated once again in FIG. 6g, the mask layer 9 remains on the top surface 2a of the structural layer 2 also at the end of the planarization process (which, in this case, involves the sole swellings of the columnar structures 8), thus constituting a mask of a hard-mask type also for the subsequent steps of the manufacturing process.

In this regard, at the end of the process of filling of the deep trenches 4 and of formation of the columnar structures 8, the manufacturing process proceeds with formation, at least in part within the structural layer 2 and using the same columnar structures 8, of a semiconductor device, for instance a semiconductor power device, such as a power MOSFET. In particular, the pitch of the structure of the power device is defined by the periodicity of the process of definition and filling of the deep trenches 4.

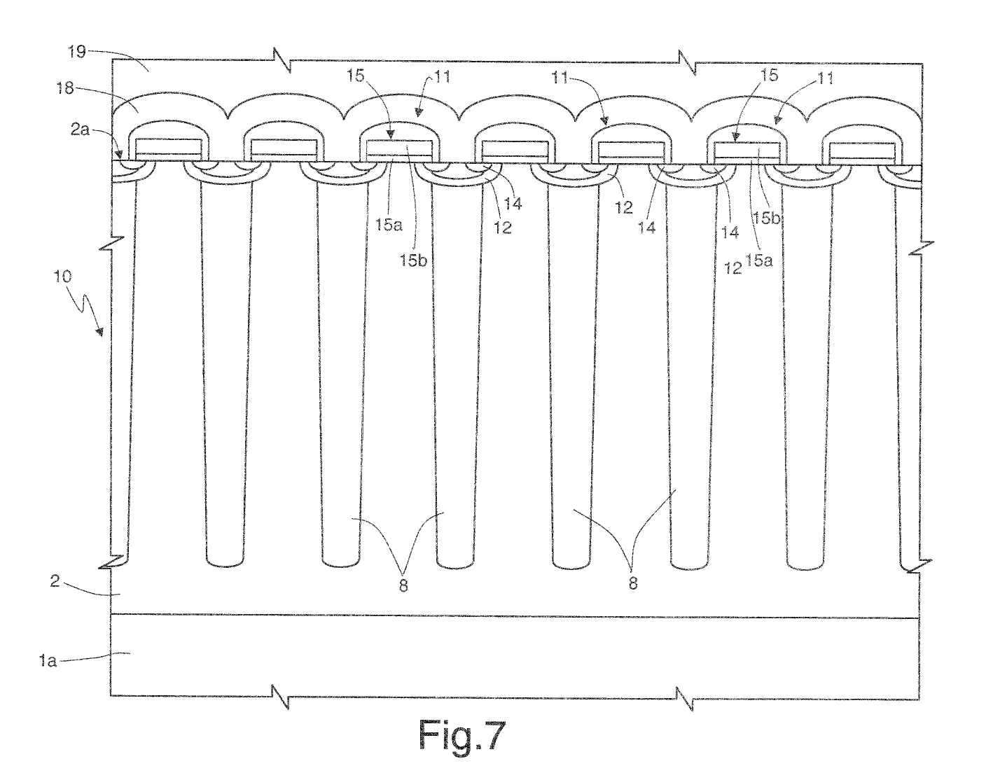

FIG. 7 shows, by way of example, a power MOSFET device, designated by 10, provided with techniques in themselves known, and for this reason not described in detail herein.

The power MOSFET device 10, of a planar type, has a periodic-strip structure given by the repetition of a plurality of elementary transistors 11, each of which includes: a body well 12, with a doping of a P type, arranged at the top surface 2a, in direct contact with a respective columnar structure 8 (which constitutes the extension thereof in the drain region, which is in turn constituted by the structural layer 2); source regions 14, with a doping of an N type, arranged within the body well 12; and an insulated-gate structure 15, which is in turn formed by the superposition of a silicon-oxide region 15a and a polysilicon region 15b, set at least partially above a source region 14 and extending between two adjacent body wells 12 of the power MOSFET device 10.

A passivation layer 18 and a metallization layer 19 are arranged, in a known way, on the top surface 2a of the structural layer 2 and of the insulated-gate structures 15.

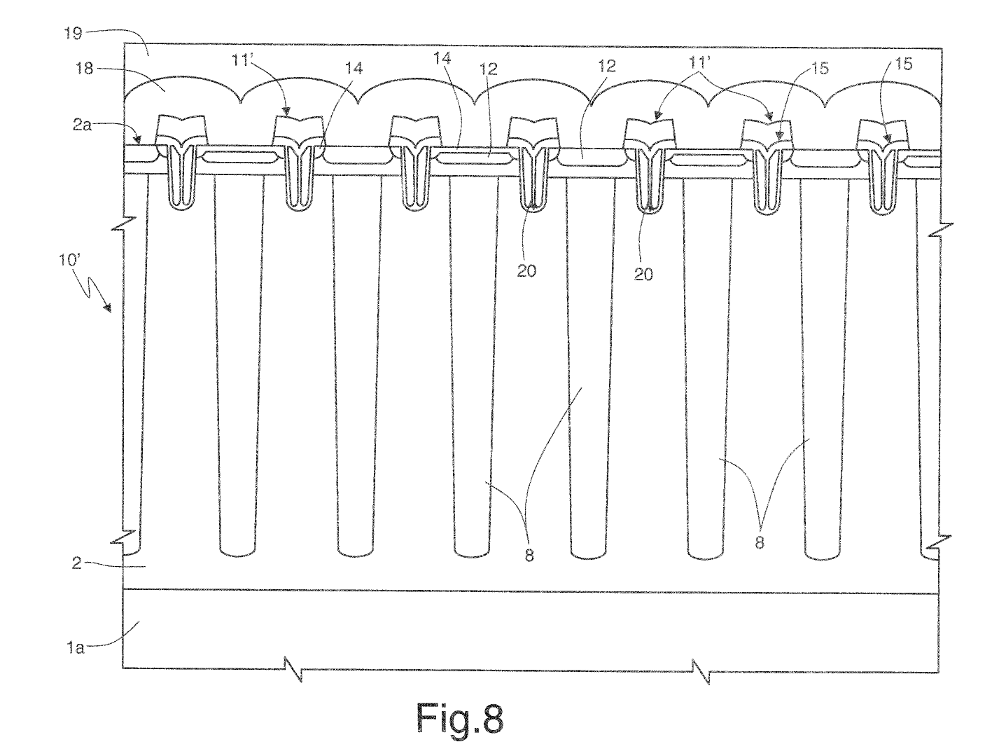

FIG. 8 shows a variant of the power MOSFET device, designated here by 10′, including a plurality of elementary transistors 11′.

In this case, the insulated-gate structures 15 are provided within gate trenches 20 dug in surface portions of the structural layer 2 arranged between adjacent columnar structures 8. The body wells 12, with a doping of a P type, are formed by a doped surface layer, traversed periodically by the gate trenches 20; source regions 14, with a doping of an N type, are again arranged within the body wells 12, just as the passivation layer 18 and the metallization layer 19 are also in this case arranged on the top surface 2a of the structural layer 2 and of the insulated-gate structures 15 (as shown in the aforesaid FIG. 8).

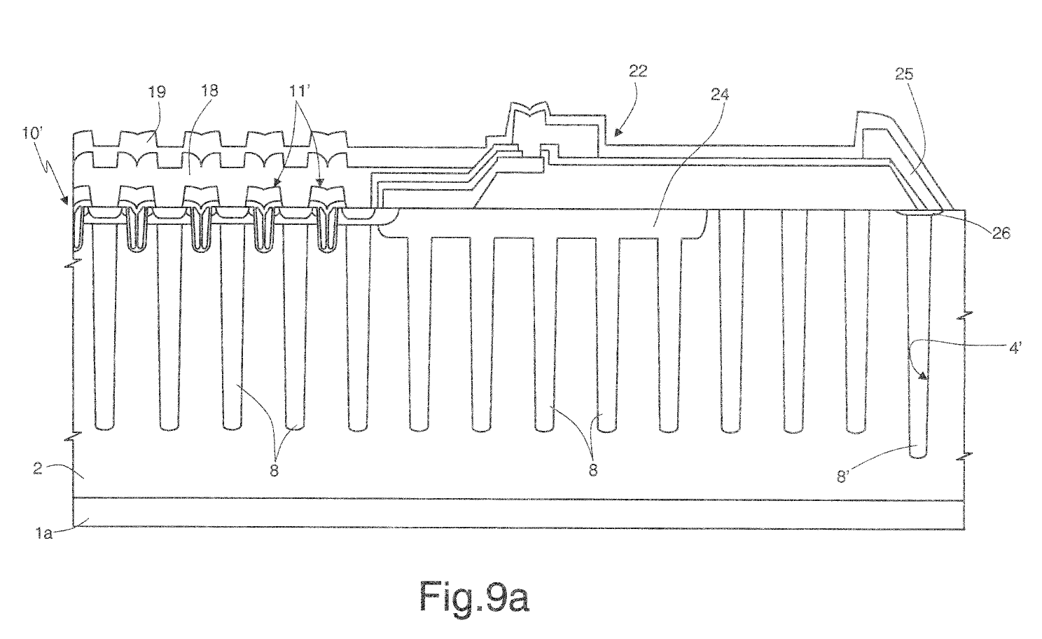

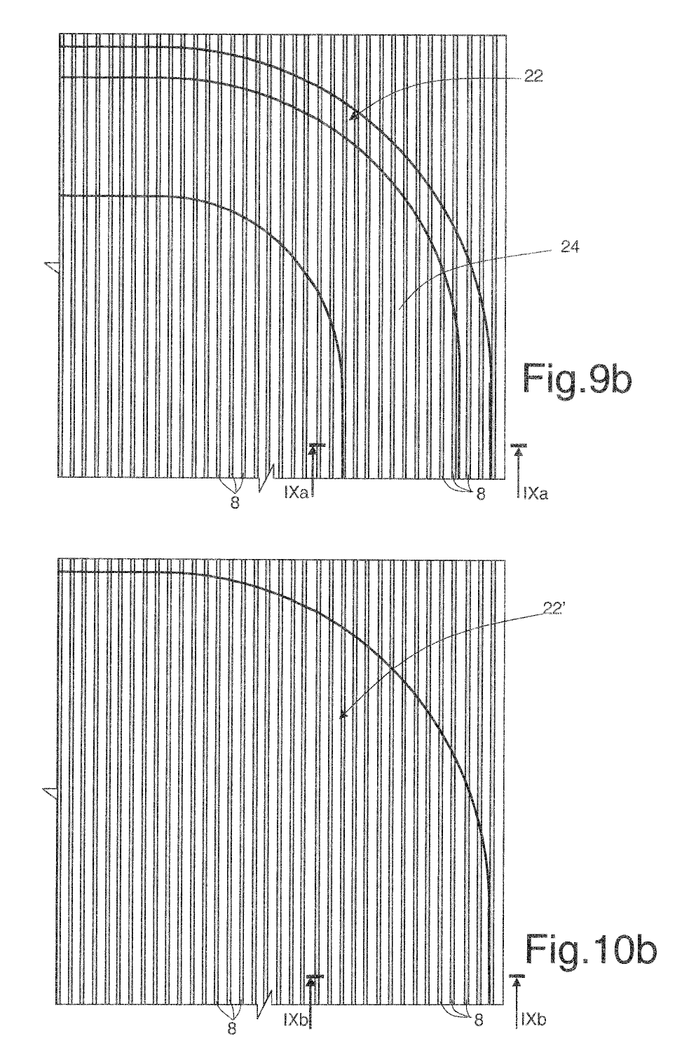

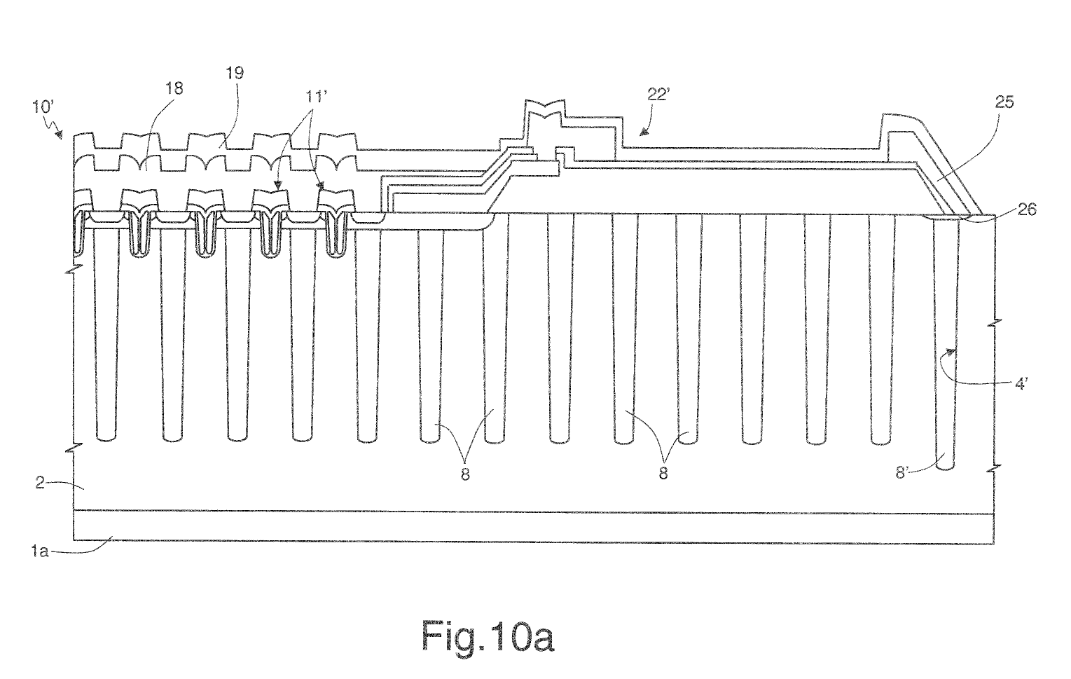

Due to effects of termination of the structure and “loading” effects during the etching steps of the manufacturing process, the last deep trench, designated by 4′ in the subsequent FIGS. 9a and 10a, of the device (i.e., the trench set closest to the scribe line) may be wider and/or deeper. Consequently, it may happen that, during the filling process, defects are formed (in particular one or more residual voids) within this terminal trench.

To prevent problems, it may be hence convenient not to use this last deep trench 4′, and the corresponding last columnar structure, designated by 8′ once again in FIGS. 9a and 10a, in an active way in the resulting semiconductor device, in effect rendering the trench a “dummy” trench.

In addition, it is convenient to prevent the field lines in reverse biasing from reaching this last columnar structure 8′, in particular by providing an appropriate edge-termination structure.

FIGS. 9a and 9b show (indicatively and not in scale), by way of example, a cross section and a simplified top plan view, respectively, of a portion of an edge structure, designated as a whole by 22, of the power MOSFET device 10′ described with reference to FIG. 8 (similar considerations clearly apply to the power MOSFET device 10 of FIG. 7 or to other semiconductor devices that may be provided by including the columnar structures 8, as part of the same devices).

In a similar way, FIGS. 10a and 10b show (indicatively and not in scale) a cross section and a simplified top plan view, respectively, of a portion of an edge structure, designated as a whole by 22′, of the power MOSFET device 10′ described with reference to FIG. 8, in a different embodiment.

The edge structures 22, 22′ are discussed in detail in the U.S. Application Publication No. US2010/0163972A1, which is incorporated by reference herein in its entirety.

The two embodiments shown in FIGS. 9a-9b and in FIGS. 10a-10b, respectively, are distinguished in that: in the former there is a surface ring 24, with a low-concentration doping of a P type, which connects some of the columnar structures 8 set in a region corresponding to the edge-termination structure 22; whilst in the latter embodiment, this surface ring is absent, and all the columnar structures 8 are floating. In either case, the edge-termination structure 22, or 22′ prevents the field lines from reaching the last columnar structure 8′ (which has a greater depth in the case shown).

It is noted moreover that an EQR (Equipotential Ring) metallization 25 contacts a doped region 26, in particular a doped region having conductivity of an N type, provided in the surface portion of the structural layer 2, in contact with the aforesaid last columnar structure 8′. The doped region 26 surrounds the entire device and has the function of bringing to the surface the drain potential, so as to horizontally limit electric field lines in reverse biasing.

The advantages of the manufacturing process according to the present disclosure emerge evidently from the foregoing description.

It is emphasized in any case that this process enables a complete filling, free from residual defectiveness, of deep trenches that have high aspect ratios. For instance, the columnar structures resulting from the uniform filling may have a depth of 30 μm by a width of between 1.5 μm and 3 μm; or else a depth of 10 μm by a width of between 0.5 μm and 1.5 μm.

In addition, the process is fast (given that it envisages a concomitant step of epitaxial growth, etching for modulation of the epitaxial growth, and doping) and inexpensive to implement; in particular, the number of process steps is lower as compared to conventional technologies, for instance, current multidrain (MD) technology.

The distribution of the dopant (as well as the dopant species) within the columnar structures formed at the end of the filling process may be modulated according to the specific applicational requirements; for instance, it may be constant throughout the depth of the columnar structure or may have an appropriate concentration gradient.

In one embodiment, the columnar structures are doped uniformly so as to obtain a charge balance with the doping of the structural layer through which the columnar structures extend, so as to form multidrain or superjunction devices.

Outside the epitaxially filled columnar structures (i.e., in the conduction area, for example, having a doping of an N type), the dopant profile is without gradient; in fact, the dopant introduced is confined in the region of the deep trenches, which are to be filled epitaxially, and moreover the device is produced with minimal thermal budget, seeing that the columnar structures are the result of a single epitaxial process, which leads to the formation of intrinsically continuous and uniform columnar structures, without requiring additional thermal processes. The constant dopant profile in the conduction area advantageously enables reduction in the conduction resistance (Rₒₙ) per unit area.

In addition, the manufacturing process is compatible with a wafer of large dimensions (for example 8″ or 12″), and enables periodic structures pitches of low value, for example less than 8 μm, to be obtained. The process moreover facilitates increase in the voltage class of the resulting devices, and can, for example, be applied to power devices with breakdown voltage that ranges from 50 V to 2000 V, according to the initial depth of the trenches.

In general, the process described enables improvement of the reliability and quality of the resulting semiconductor devices.

Finally, it is clear that modifications and variations may be made to what has been described and illustrated herein, without thereby departing from the scope of the present disclosure.

In particular, it is evident that the features of the substeps of epitaxial growth and concomitant etching of the material grown (and possibly of the pre-existing material), in which the process of filling of the deep trenches is divided, can vary with respect to what has been illustrated; for instance the ratio between the flows of gas supplied in the reaction chamber (Φ_{HCl}/Φ_{DCS}) and the consequent growth/etching regime with which these substeps are carried out, or the duration of the same steps, may vary. The process can in fact be modulated and adapted to various and specific requirements and applications.

As already emphasized, also the flow of the dopant species in the reaction environment for epitaxial growth may vary, so as to obtain different and in any case controlled doping profiles (possibly even ones that include different dopant species).

In addition, it is evident that modifications may be made also from the structural standpoint: for instance, the deep trenches (and the corresponding columnar structures) may extend as far as the underlying substrate and partially within the substrate itself; the semiconductor devices provided may equivalently have P channels or N channels, just as the columnar structures can have doping of an N type, instead of a P type.

As already emphasized, the process of filling of the deep trenches can find advantageous application in a wide range of fields, apart for the manufacturing of semiconductor power devices; for example, via a columnar structure resulting from the filling process described (which in this case can envisage filling even of just one deep trench), a sinker can be provided for a semiconductor device, designed to bring to the surface the potential of a buried region (for example, a drain region).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A process for manufacturing a semiconductor device, comprising:
providing a deep trench in a body of semiconductor material body, the trench extending through said body of semiconductor material starting from a top surface of the body; and
forming a columnar structure within said body by filling said deep trench via an epitaxial growth of semiconductor material, the forming including:
modulating said epitaxial growth by concurrently chemically etching the semiconductor material that is undergoing epitaxial growth, wherein said filling comprises introducing, in a reaction environment for epitaxial growth, a flow of a source gas for said epitaxial growth; and said modulating comprises introducing, in the same reaction environment as that of the epitaxial growth, a flow of an etching gas, to mix with said flow of source gas;
and wherein said modulating comprises performing a sequence of a plurality of modulating substeps, each of which distinguished by a respective ratio between said flow of source gas and said flow of etching gas supplied in said reaction environment for the epitaxial growth and concurrent chemical etching.

2. The process according to claim 1, wherein said semiconductor material is silicon, said source gas is dichlorosilane and said etching gas is hydrochloric acid.

3. The process according to claim 1, wherein said modulating comprises adjusting a ratio between said flow of source gas and said flow of etching gas to define a desired growth/etching regime that is variable along a depth of said deep trench.

4. The process according to claim 3, wherein said adjusting comprises adjusting a ratio between said flow of source gas and said flow of etching gas and defining a higher rate of growth of said semiconductor material at a bottom of said deep trench, set at a distance from said top surface, than at said top surface.

5. The process according to claim 3, wherein providing said deep trench includes providing said deep trench with a width having an initial value parallel to, and at, said top surface, and walls having an inclination with an initial value with respect to a direction orthogonal to said top surface; and wherein said modulating comprises modifying a shape of said deep trench in such a way as to increase said width as compared to said initial value, and in such a way as to increase said inclination as compared to said initial value.

6. The process according to claim 1, wherein said plurality of modulating substeps comprises:
a first modulating substep, carried out in growth regime throughout a depth of said deep trench and such as to provide a rate of growth of said semiconductor material that is higher at a bottom of said deep trench than at said top surface;
a second modulating substep, subsequent to said first modulating substep, carried out in etching regime for a portion of said deep trench near said top surface, and such as to provide a rate of etching of said semiconductor material that is higher at said top surface than at said bottom of said deep trench; and
a third modulating substep, subsequent to said second modulating substep, carried out in growth regime throughout the depth of said deep trench, and such as to provide a substantially complete filling of said deep trench.

7. The process according to claim 6, wherein said plurality of modulating substeps further comprises:
a fourth modulating substep, subsequent to said third modulating substep, carried out in growth regime throughout a residual depth of said deep trench, which remains following upon said third modulating substep, and such as to determine a complete filling of said deep trench and formation of said columnar structure within said body of semiconductor material.

8. The process according to claim 1, further comprising doping said columnar structure; said doping including introducing in said reaction environment a flow of a dopant gas to dope said semiconductor material, said introducing causing said flow of dopant gas to mix with said flow of source gas and with said flow of etching gas in the same reaction environment as that of said epitaxial growth.

9. The process according to claim 8, wherein said doping comprises, during said epitaxial growth, varying said flow of dopant gas as a function of a variation of said flow of etching gas to take into account an effect of depletion of said dopant gas caused by said etching gas.

10. The process according to claim 9, wherein said doping comprises doping with a uniform profile said columnar structure throughout a depth of the columnar structure; and wherein said varying comprises varying said flow of dopant gas in a way corresponding to the variation of said flow of etching gas, during said epitaxial growth.

11. The process according to claim 8, wherein said dopant gas is diborane.

12. The process according to claim 1, further comprising, prior to said filling, forming a mask layer on said top surface of said body of semiconductor material, said mask layer having an opening in an area corresponding to said deep trench; and wherein said filling is carried out in the presence of said mask layer in such a way that said epitaxial growth occurs in a selective way within said deep trench.

13. The process according to claim 1, wherein said body of semiconductor material has a plurality of deep trenches extending through the body starting from said top surface; and said forming includes forming a plurality of columnar structures within said body of semiconductor material by filling, with the same epitaxial growth of semiconductor material said deep trenches, the plurality of columnar structures having a doping such as to balance an amount of charge, of an opposite type, of said body of semiconductor material.

14. The process according to claim 13, further comprising forming a doped device region in direct contact with a respective one of said columnar structures.

15. The process according to claim 14, wherein said semiconductor device is a charge-balance power device.

16. A process for manufacturing a semiconductor device, comprising:
providing a deep trench in a body of semiconductor material body, the trench extending through said body of semiconductor material starting from a top surface of the body; and
forming a columnar structure within said deep trench, the forming including:
performing a first epitaxial growth of semiconductor material in the trench by concurrently supplying to a reaction chamber a first flow of a source gas for epitaxial growth and a first flow of an etching gas in a first ratio of source gas to etching gas; and
performing a second epitaxial growth of semiconductor material in the trench by concurrently supplying to the reaction chamber a second flow of source gas for epitaxial growth and a second flow of an etching gas in a second ratio of source gas to etching gas, the second ratio being different than the first ratio.

17. The process according to claim 16, wherein said semiconductor material is silicon, said source gas is dichlorosilane and said etching gas is hydrochloric acid.

18. The process according to claim 16, wherein performing the first epitaxial growth includes performing a higher rate of epitaxial growth of said semiconductor material at a bottom of said deep trench than a rate of epitaxial growth performed during the second epitaxial growth at said top surface.

19. The process according to claim 16, wherein:
providing said deep trench includes providing said deep trench with a width having an initial value parallel to, and at, said top surface, and walls having an inclination with an initial value with respect to a direction orthogonal to said top surface; and
performing the first epitaxial growth includes modifying a shape of said deep trench in such a way as to increase said inclination as compared to said initial value.

20. The process according to claim 16, wherein:
performing the first epitaxial growth includes providing a rate of growth of said semiconductor material that is higher at a bottom of said deep trench than at said top surface;
performing the second epitaxial growth includes performing the second epitaxial growth subsequent to performing the first epitaxial growth and providing a rate of etching of said semiconductor material that is higher at said top surface than at said bottom of said deep trench, the process further comprising:
performing a third epitaxial growth of the semiconductor material subsequent to performing the second epitaxial growth and providing a substantially complete filling of said deep trench.

21. The process according to claim 20, further comprising:
performing a fourth epitaxial growth of the semiconductor material subsequent to performing the third epitaxial growth includes completely filling a residual depth of said deep trench which remains following performing the third epitaxial growth.

22. The process according to claim 16, further comprising doping said columnar structure; said doping including introducing in said reaction chamber a flow of a dopant gas to dope said semiconductor material, said introducing causing said flow of dopant gas to mix with said second flow of source gas and with said second flow of etching gas in the reaction chamber during performing the second epitaxial growth.

23. The process according to claim 16, further comprising, prior to performing the first epitaxial growth, forming a mask layer on said top surface of said body of semiconductor material, said mask layer having an opening in an area corresponding to said deep trench; and wherein performing the first epitaxial growth is carried out in the presence of said mask layer in such a way that epitaxial growth occurs in a selective way within said deep trench.
